(19) United States
(12) Patent Application Publication
(10) Pub. No.: US 2026/0005088 A1
(43) Pub. Date: Jan. 1, 2026

(54) SEMICONDUCTOR PACKAGE HAVING A THREE-DIMENSIONAL PRINTED ENCLOSURE

(71) Applicant: SanDisk Technologies LLC, Austin, TX (US)

(72) Inventors: MUHAMAD RIDHWAN HAFIZ BIN ROSDI, PULAU PINANG (MY); MUHAMMAD FAIZUL MOHD YUNUS, PENANG (MY); CINDIRELLA QUINIT NOROMOR, PULAU PINANG (MY); HUBERT TOLENTINO HELERA, ALAMINOS (PH); THINES RAVENDRAN, PENANG (MY)

(21) Appl. No.: 18/754,628

(22) Filed: Jun. 26, 2024

(51) Int. Cl. H01L 23/31; H01L 21/56; H01L 23/00; H01L 23/29; H01L 23/544

(52) U.S. Cl. CPC H01L 23/3121; H01L 21/565; H01L 23/29; H01L 23/544; H01L 24/48; H01L 2223/5442; H01L 2224/48225; H01L 2924/1438

(57) ABSTRACT

A semiconductor package includes a number of electronic components surrounded or enclosed by a 3D printed enclosure. The 3D printed enclosure is formed by a 3D printing process that uses a thermosetting liquid resin as a molding compound. The 3D printing process includes immersing the electronic components in the thermosetting liquid resin. When the electronic components have been immersed in the thermosetting liquid resin, one or more light sources are selectively activated to cure the thermosetting liquid resin which forms the enclosure. In addition to forming the enclosure, the thermosetting liquid resin and the curing process is also used to form various markings on the enclosure.

### BACKGROUND

Most semiconductor packages include an enclosure that houses and protects the various integrated circuits and semiconductor dies that are part of the semiconductor package. The enclosure is typically formed during a molding process, such as a transfer molding process or a compression molding process.

In a transfer molding process, a substrate, along with the various integrated circuits and semiconductor dies, are placed in a mold. A molding compound is added to a chamber and heated which reduces the viscosity of the molding compound. Pressure is applied to the chamber which causes the molding compound to exit the chamber and enter the mold. The molding compound flows around and surrounds the integrated circuits and semiconductor dies. A heating process cures the molding compound to form the enclosure.

Similarly, in a compression molding process, a substrate, along with various electronic components, are placed in a mold of a compression molding machine. A molding compound is then added to the mold of the compression molding machine. The molding compound is heated to a desired temperature. The mold is closed and pressure is applied to the mold which forces the molding compound to fill a cavity of the mold. As a result, the semiconductor dies and the integrated circuits are encapsulated by the molding compound.

However, each of these molding processes has several drawbacks. For example, when the molding compound is forced into the mold and flows around the various components, the flow of the molding compound may cause bond wires of the semiconductor package to move, sag, become disconnected and/or contact each other, thereby causing shorts and other issues. In other examples, the semiconductor dies may be stacked on top of one or more spacers that form a tunnel within the semiconductor package. If the tunnel is not a particular height and/or length, the molding compound may not completely fill the tunnel.

Accordingly, it would be beneficial for a molding process to reduce the risk that bond wires will be damaged or moved during the molding process and to reduce the risk that a tunnel of the semiconductor package will not be completely filled during the molding process.

### SUMMARY

The present disclosure describes a molding process that forms an enclosure for an electronic device, such as, for example, a semiconductor package. In an example, the enclosure is formed by a three-dimensional (3D) printing process that uses a thermosetting liquid resin as a molding compound. For example, when one or more electronic components have been mounted or otherwise placed on a substrate of the electronic device, the electronic components are immersed in the thermosetting liquid resin.

When the electronic components have been immersed in the thermosetting liquid resin, a curing process is initiated. The curing process uses various light sources (e.g., ultraviolet light sources) that are selectively activated. For example, during the curing process, different light sources are activated to cure different layers or portions of the enclosure and/or to form different patterns, shapes and/or markings on/for the enclosure.

In examples, a viscosity of the thermosetting liquid resin is between one-hundred centipoise and three-thousand centipoise. The viscosity of the thermosetting liquid resin used in the molding process described herein reduces the risk of bond wire movement and/or damage during the molding process and also reduces the risk that one or more tunnels of the semiconductor package will not be filled with the molding compound—especially when compared with current molding compounds that have a viscosity of 12,000 centipoise. Additionally, due to the curing process used, the enclosure may have any desired shape, size and/or marking without the need for separate molding and marking processes.

Accordingly, examples of the present disclosure describe a method for encapsulating an electronic device. The method includes providing a substrate having a first side with a plurality of components secured thereto. The method also includes three-dimensional (3D) printing a mold compound on the first side of the substrate such that the mold compound covers the plurality of components.

Other examples describe a semiconductor package having a substrate and a plurality of electronic components mounted on the substrate. An enclosure at least partially surrounds the plurality of electronic components. In an example, the enclosure is formed by a three-dimensional (3D) printing process in which the plurality of electronic components are immersed in a thermosetting liquid resin.

The present disclosure also describes a semiconductor package that includes a substrate and at least one semiconductor die mounted on the substrate. A communication means electrically couples the at least one semiconductor die to the substrate and a three-dimensional (3D) printed enclosing means at least partially surrounds the at least one semiconductor die and the communication means.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates a semiconductor package having a 3D printed enclosure according to an example.

FIG. 1B illustrates a top view of the 3D printed enclosure of the semiconductor package of FIG. 1A according to an example.

FIG. 1C illustrates a semiconductor package having a 3D printed enclosure according to another example.

FIG. 2A illustrates a first operation of an encapsulation process for forming a 3D printed enclosure for a semiconductor package according to an example.

FIG. 2B illustrates a second operation of the encapsulation process for forming the 3D printed enclosure for the semiconductor package according to an example.

FIG. 2C illustrates a third operation of the encapsulation process for forming the 3D printed enclosure for the semiconductor package according to an example.

FIG. 2D illustrates a fourth operation of the encapsulation process for forming the 3D printed enclosure for the semiconductor package according to an example.

FIG. 3 illustrates a method for forming an enclosure for a semiconductor package according to an example.

FIG. 4 is a system diagram of a computing device according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

Most semiconductor packages include various integrated circuits and semiconductor dies mounted on a substrate. An enclosure typically surrounds the semiconductor dies and the integrated circuits and protects these components from damage. The enclosure is formed during a molding process in which a molding compound is added to a mold in which the substrate and electronic components have been placed. A molding compound is added to the mold and flows around and surrounds the electronic components.

However, due to the high viscosity of the molding compound, the flow of the molding compound may cause bond wires of the semiconductor package to move, sag, become disconnected and/or contact each other, thereby causing shorts and other issues. In other examples, the high viscosity of the molding compound prevents the molding compound from completely filling a tunnel of the semiconductor die. As a result, the semiconductor package may become more easily damaged, have less than optimal thermal dissipation properties, have reliability issues or face a host of other problems.

To address the above, the present disclosure describes a three-dimensional (3D) printing process that forms an enclosure for a semiconductor package. However, unlike traditional 3D printing processes in which a spool of plastic filament is fed into a heat source where it is melted and subsequently extruded onto a surface, the 3D printing process uses a thermosetting liquid resin as a molding compound. For example, when an enclosure is to be formed around the various electronic components of the semiconductor package, a substrate on which the electronic components are placed is provided on a first molding section of a molding machine. The electronic components are immersed in the thermosetting liquid resin that is contained in a second molding section of the molding machine.

When the electronic components have been immersed in the thermosetting liquid resin, a curing process is initiated. During the curing process, various ultraviolet lights are selectively activated. For example, during the curing process, different ultraviolet lights are activated to cure different layers of the enclosure and/or to form different patterns, shapes and/or markings on/for the enclosure. In an example, the ultraviolet light curing process is faster and more accurate when compared with traditional curing processes that use heat. As a result, more intricate designs for semiconductor packages and enclosure designs are possible using the examples described herein when compared with current solutions.

In examples, a viscosity of the thermosetting liquid resin is relatively low when compared with current molding compounds. For example, a viscosity of typical molding compounds is approximately 12,000 centipoise. However, the viscosity of the thermosetting liquid resin is between one-hundred centipoise and three-thousand centipoise. As such, the risk of bond wire movement and/or damage during a molding process and/or the risk that a tunnel of the semiconductor package will not be filled with the molding compound is substantially reduced when compared with current solutions. Additionally, due the curing process used, the enclosure may have any desired shape, size and/or marking. Additionally, and unlike current solutions in which an encapsulation process and a marking process are two separate processes, examples of the present disclosure combine the encapsulation and marking processes, thereby increasing throughput and efficiency.

Accordingly, many technical benefits may be realized including, but not limited to, increasing the unit per hour yield by combining a molding process and a marking process into a single operation, enabling more complex bond wire and/or tunnel designs for semiconductor packages while reducing the risk of bond wire damage and incomplete tunnel fill, and reducing an overall height of the semiconductor package as a result of the low viscosity thermosetting liquid resin being able to fill small pitch areas.

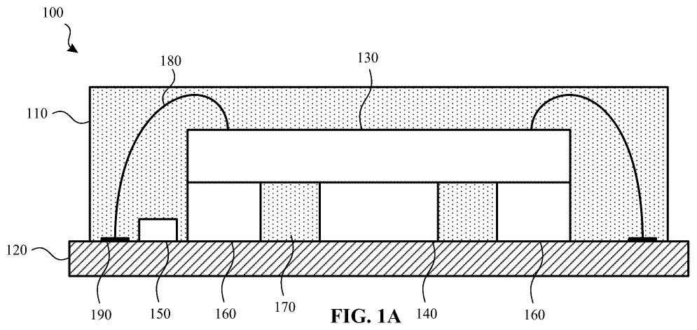

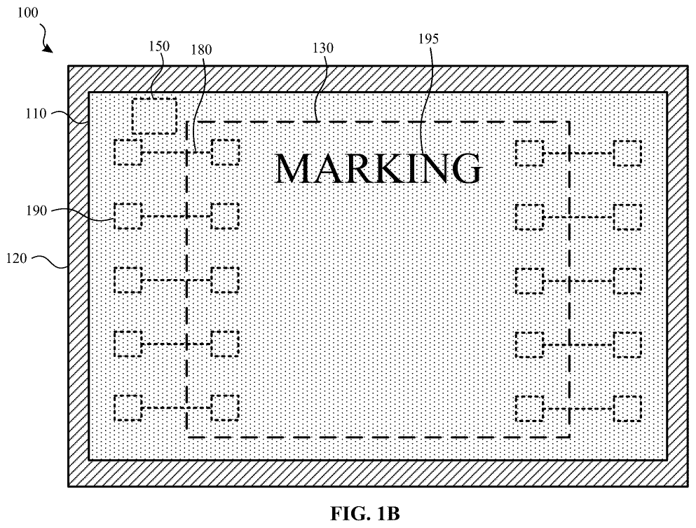

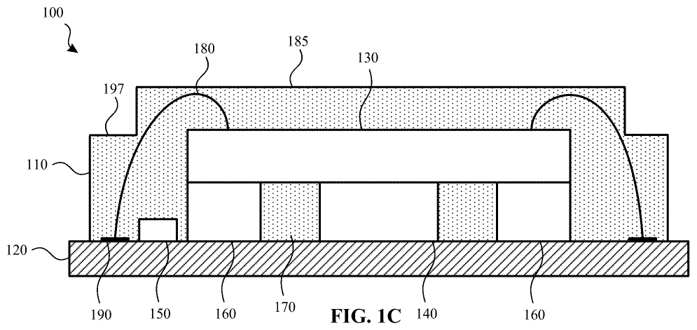

These and other examples will be described in more detail with respect to FIG. 1A-FIG. 4.

FIG. 1A illustrates a semiconductor package 100 having a 3D printed enclosure 110 according to an example. As will be explained in greater detail herein, the 3D printed enclosure 110 is formed by an encapsulation process that utilizes a thermosetting liquid resin and a light source curing process.

The semiconductor package 100 includes a number of electronic components. In an example, the semiconductor package 100 includes at least one semiconductor die 130, at least one integrated circuit 140 and/or at least one passive component 150. For example, the semiconductor package 100 is a NAND memory package. As such, the semiconductor die 130 is a NAND memory die (or a stack of NAND memory dies), the integrated circuit 140 is a controller and the passive component 150 is a resistor, a capacitor, a transistor or other such component. Although a NAND memory package is specifically mentioned, the semiconductor package 100 may be any semiconductor package having an enclosure.

In an example, the semiconductor package 100 also includes one or more spacers 160. The spacers 160 are placed on the substrate 120 and the semiconductor die 130 is placed on top of the spacers 160. The spacers 160 and the semiconductor die 130 define or otherwise form a tunnel 170. In the example shown in FIG. 1A, the integrated circuit 140 is placed between the spacers 160 and underneath the semiconductor die 130.

Although a particular arrangement is shown and described, the semiconductor package 100 can have additional spacers (e.g., between different NAND memory dies of a stack of NAND memory dies) or the spacers 160 can be omitted. Additionally, the integrated circuit 140 may be placed at any location on the substrate 120 and need not be placed between the spacers 160 and/or underneath the semiconductor die 130.

In an example, the semiconductor package 100 also includes a number of bond wires 180. The bond wires 180 electrically couple the semiconductor die 130 to corresponding bond pads 190 on the substrate 120. Although a single bond wire 180 is shown on either side of the semiconductor die 130, multiple bond wires may be used to electrically and/or communicatively couple the semiconductor die 130 (or multiple different semiconductor dies in a stack of semiconductor dies) to the substrate 120.

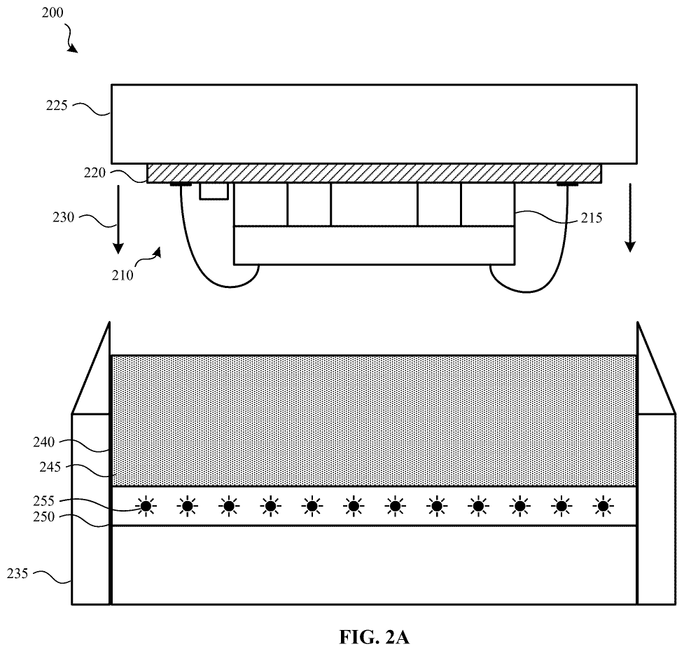

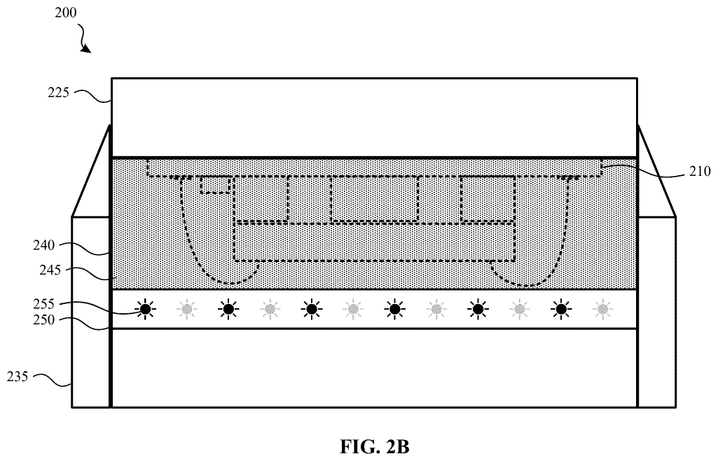

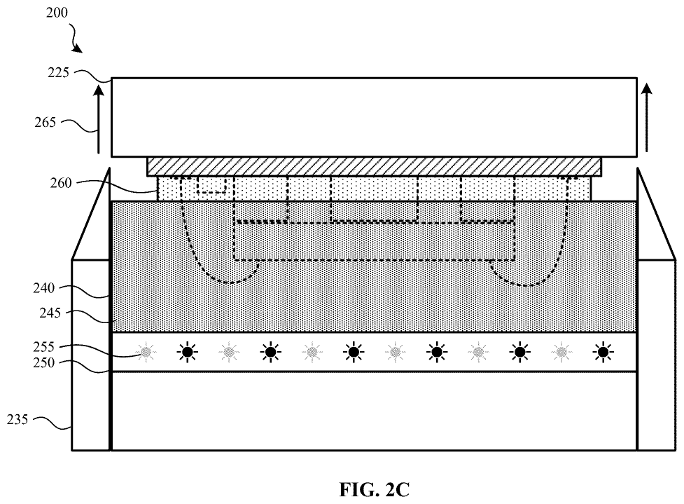

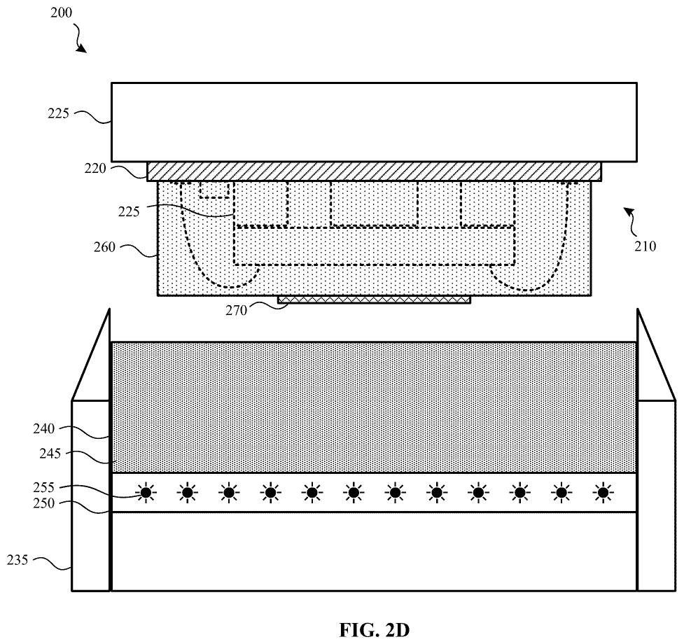

As briefly explained above, the 3D printed enclosure 110 of the semiconductor package 100 is formed by an encapsulation process or a 3D printing process that utilizes a thermosetting liquid resin and an ultraviolet light curing process. As will be explained in greater detail with respect to FIG. 2A-FIG. 2D, the thermosetting liquid resin that is used as part of the encapsulation process has a viscosity of between one-hundred centipoise and three-thousand centipoise. Although a specific range is given, the viscosity of the thermosetting liquid resin can be below one-hundred (e.g., fifty) or above three-thousand (e.g., four-thousand or higher).

Because the thermosetting liquid resin has a low viscosity (especially when compared with the viscosity of currently used epoxy molding compounds), the risk of the bond wires 180 bending, sagging, becoming disconnected from the semiconductor die 130 and/or the bond pad 190 is significantly reduced when compared with current encapsulation processes (e.g., compaction molding processes and/or transfer molding processes). As such, longer and/or higher bond wires 180 can be used in various semiconductor packages 100 (e.g., when compared with current solutions).

Additionally, because the thermosetting liquid resin has a low viscosity, the risk that the tunnel 170 will not be completely filled by the thermosetting liquid resin is also significantly reduced when compared with current encapsulation processes. As a result, a semiconductor package 100 having longer and/or shorter (e.g., in terms of Z-height) tunnels 170 can be designed.

In other examples, the encapsulation process that was used to create the 3D printed enclosure 110 may also reduce or eliminate one or more operations that are typically required during a semiconductor fabrication process. For example, in current encapsulation processes, the enclosure is formed using particular equipment and/or machinery. When the enclosure has been formed, a marking process is initiated. The marking processes typically uses different equipment and/or machinery.

For example, the encapsulation processes uses a compression molding machine to form the enclosure while the marking process utilizes a high powered laser to create a permanent mark on the surface of the enclosure. During the marking process, energy from the laser causes the molding compound of the enclosure to vaporize or melt which creates a mark on the surface of the enclosure. Not only do these two processes require the use of different equipment, there is a risk that the laser will melt too much of the molding compound and damage the electronic components of the semiconductor package.

To address this, the encapsulation process described herein combines an encapsulation process and a marking process into a single operation. For example, the encapsulation process enables the marking to be formed directly on the 3D printed enclosure 110 during the encapsulation process. For example, during a curing process of the encapsulation process, one or more light sources (e.g., ultraviolet light sources) are selectively activated to cure various portions of the 3D printed enclosure 110. As a result, the 3D printed enclosure 110 can take any shape, any size and/or have any number of markings provided on a surface. For example and referring to FIG. 1C, a first portion 185 of the 3D printed enclosure 110 has a first height, design and/or marking while a second portion 197 of the 3D printed enclosure 110 has a second height, design and/or marking.

FIG. 1B illustrates a top view of the 3D printed enclosure 110 of the semiconductor package of FIG. 1A according to an example. It is understood that similarly numbered and/or named components may function in a similar fashion such as previously described with respect to FIG. 1A. As such, redundant explanation of these components has been omitted for clarity.

As shown in FIG. 1B, the 3D printed enclosure 110 includes a marking 195 provided on a top surface. In an example, the marking 195 may be any type of marking including, but not limited to, text, numbers, images, shapes and/or other such markings. Because the marking 195 is created as part of the encapsulation process, a laser marking operation or process can be eliminated. As such, the number of units per hour may be increased while also reducing costs (e.g., when compared with current molding and laser marking processes).

In an example, the marking 195 is a raised marking (e.g., the marking 195 extends above a top surface of the 3D printed enclosure 110). In another example, the marking 195 is a recessed marking (e.g., the marking 195 is below the top surface of the 3D printed enclosure 110). In yet other examples, the marking 195 (or multiple different markings) may be placed at any location on the 3D printed enclosure 110. As will be explained in greater detail below, the marking 195 is formed by selectively activating one or more light sources during a curing process of the encapsulation process.

FIG. 2A-FIG. 2D illustrate various different operations in a semiconductor package encapsulation process according to an example. In an example, the operations shown and described with respect to FIG. 2A-FIG. 2D are used to form the 3D printed enclosure 110 of the semiconductor package 100 shown and described with respect to FIG. 1A-FIG. 1B.

FIG. 2A illustrates a first operation of an encapsulation process for forming a 3D printed enclosure for a semiconductor package 210 according to an example. In an example, the first operation of the encapsulation process begins when various electronic components 215 have been mounted on a substrate 220 or a printed circuit board (PCB) to form the semiconductor package 210. In an example, the semiconductor package 210 is similar to the semiconductor package 100 shown and described with respect to FIG. 1A. As such, the electronic components 215 include one or more semiconductor dies, one or more integrated circuits, one or more passive components and the like.

When the semiconductor package 210 has been fabricated, the semiconductor package 210 is mounted on first molding section 225 of an encapsulation or molding machine 200. In an example, the semiconductor package 210 is mounted on the first molding section 225 such that the electronic components 215 of the semiconductor package 210 are facing or are otherwise directed toward a second molding section 235 of the molding machine 200.

For example, a first side of the substrate 220 of the semiconductor package 210 is removably coupled to (e.g., via suction, tape, vacuum etc.) the first molding section 225 of the molding machine 200. As such, a second side of the substrate 220 on which the electronic components 215 are placed are exposed to or are otherwise facing the second molding section 235.

In an example, the second molding section 235 of the molding machine 200 includes a vat or tub 240 that contains a thermosetting liquid resin 245. In an example a viscosity of the thermosetting liquid resin 245 is between one-hundred centipoise and three-thousand centipoise.

The second molding section 235 also includes a curing portion 250. The curing portion 250 includes one or more light sources 255 that are selectively activated to cure the thermosetting liquid resin 245 once the electronic components 215 have been immersed in the thermosetting liquid resin 245. In an example, the one or more light sources 255 are ultraviolet light sources. Although ultraviolet light sources are specifically mentioned, other types of light sources, or energy sources, may be used to cure the thermosetting liquid resin 245.

When the semiconductor package 210 has been mounted to the first molding section 225, the first molding section 225 is moved toward the second molding section 235 (e.g., in the direction of arrows 230). In another example, the second molding section 235 is moved toward the first molding section 225. In yet another example, the first molding section 225 and the second molding section 235 are both moveable and move toward each other.

FIG. 2B illustrates a second operation of the encapsulation process for forming the 3D printed enclosure for the semiconductor package 210 according to an example. As shown in FIG. 2B, the semiconductor package 210 has been immersed in the thermosetting liquid resin 245. Although FIG. 2B illustrates that the entire semiconductor package 210, including the substrate 220, has been immersed in the thermosetting liquid resin 245, this is not required.

When the semiconductor package 210 has been immersed in the thermosetting liquid resin 245, the curing and/or marking process may commence. For example, one or more of the light sources 255 of the curing portion 250 are selectively activated. In an example, a computing device integrated or otherwise associated with the molding machine 200 may control the duration at which the one or more light sources 255 are activated and/or which light sources are activated. In an example, different light sources are activated based on a number of factors. These factors include, but are not limited to, a layer of the 3D printed enclosure that is being cured, a desired shape of the 3D printed enclosure, a desired type and/or location of a marking that is being formed on the 3D printed enclosure and so on. In an example, the factors are provided to the computing device and the computing device causes the light sources to be activated to achieve the desired layout/design of the 3D printed enclosure.

FIG. 2C illustrates a third operation of the encapsulation process for forming the 3D printed enclosure for the semiconductor package 210 according to an example. In the example shown in FIG. 2C, when a first layer or a first portion of the 3D printed enclosure 260 has been formed, the first molding section 225 is moved away from the second molding section 235 (e.g., in the direction of the arrows 265) or vice versa. The light sources 255 may then be activated again to form a second portion or a second layer of the 3D printed enclosure 260.

In an example, the same set of light sources that were previously activated as part of the first curing process may be activated a second time. In another example, a different set of light sources 255 are activated to form the second layer or the second portion of the 3D printed enclosure 260. This process may repeat any number of times until the 3D printed enclosure 260, and any markings on the 3D printed enclosure 260, are formed.

FIG. 2D illustrates a fourth operation of the encapsulation process for forming the 3D printed enclosure 260 for the semiconductor package 210 according to an example. For example and as shown in FIG. 2D, once the various light sources 255 have been selectively activated as part of the curing process and the desired shape and/or size of the 3D printed enclosure 260 has been created, the light sources 255 may also be selectively activated to create or form a marking 270 on a surface of the 3D printed enclosure 260 such as previously described. As such, a molding process and a marking process are combined into a single operation.

The semiconductor package 210 may then be removed from the first molding section 225 and the process is repeated for another semiconductor package.

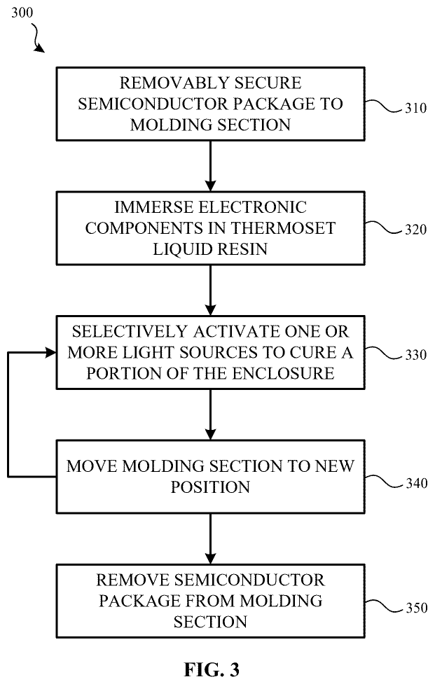

FIG. 3 illustrates a method 300 for forming an enclosure for a semiconductor package according to an example. In an example, the method 300 is executed by a computing device and is used to form a 3D printed enclosure for a semiconductor package such as, for example, the 3D printed enclosure 110 shown and described with respect to FIG. 1A-FIG. 1B. Additionally, the method 300 may use a molding machine such as, for example, the molding machine 200 shown and described with respect to FIG. 2A-FIG. 2D.

In an example, the method 300 begins when a semiconductor package is removably secured (310) to a molding section of a molding machine. For example, a first side of a substrate of the semiconductor package is removeably secured to a first portion of a molding machine such that a second side of the substrate (e.g., a side of the substrate on which one or more electronic components are mounted) is exposed or presented to a second molding section of the molding machine.

When the semiconductor package has been secured to the molding machine, the electronic components of the semiconductor package are immersed (320) in a thermosetting liquid resin. For example, the first molding section of the molding machine is moved toward the second molding section of the molding machine. In an example, the second molding section of the molding machine includes a vat or tub that contains the thermosetting liquid resin.

When the electronic components of the semiconductor package have been immersed in the thermosetting liquid resin, one or more light sources are selectively activated (330) to cure one or more portions of the enclosure. In an example, the number and/or type of light sources that are activated, and the duration of activation, is based on a number of factors and is controlled by a computing device. These factors include, but are not limited to, a layer of the enclosure that is being cured, a desired shape of the enclosure, a desired type and/or location of a marking that is being formed on the enclosure and so on.

When the portion of the enclosure has been cured, the molding section is moved (340) to a new position. As a result, a new layer or a new portion of the enclosure is formed. Operations 330 and 340 are repeated a number of times until the enclosure is completely formed. In another example, the enclosure is completely cured during operation 330. In another example, the second molding portion may include a pattern, marking or stencil on a bottom and/or side surface. Thus, when the light sources are activated and the thermosetting liquid resin is cured, the pattern, marking or stencil is also cured/formed on the enclosure.

When the enclosure and/or markings have been formed, the semiconductor package is removed (350) from the molding section and the method 300 may be repeated.

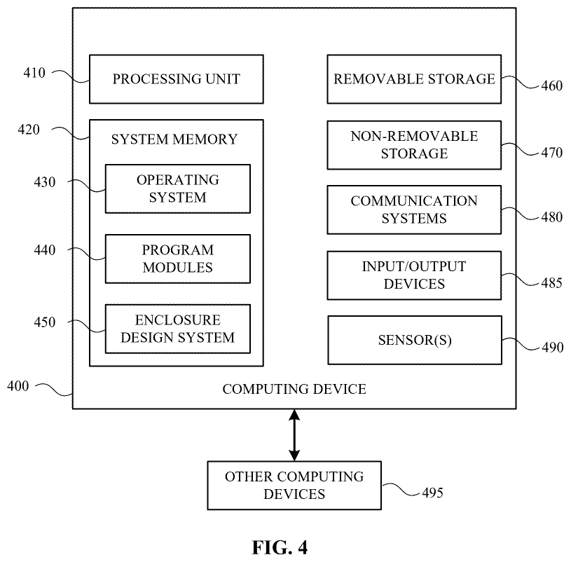

FIG. 4 is a system diagram of a computing device 400 according to an example. The computing device 400, or various components and systems of the computing device 400, may be integrated or associated with a molding machines such as, for example, the molding machine 200 shown and described with respect to FIG. 2A-FIG. 2D. Additionally, the computing device 400 may be used to execute or otherwise perform one or more operations of the method 300 shown and described with respect to FIG. 3. For example, the computing device 400, or various components or systems of the computing device 400, (e.g., an enclosure design system 450) may be used to determine a layout, design and/or markings of an enclosure. For example, the enclosure design system 450 may receive one or more requirements of the enclosure (e.g., the height, shape, markings) and cause the molding machine to form the enclosure based on the received specification/requirements. The enclosure design system 450 may also control the movement of the various sections of the molding machine and/or the activation of the various light sources. In an example, the physical components (e.g., hardware) of the computing device 400 are illustrated and these physical components may be used to practice the various aspects of the present disclosure.

The computing device 400 may include at least one processing unit 410 and a system memory 420. The system memory 420 may include, but is not limited to, volatile storage (e.g., random access memory), non-volatile storage (e.g., read-only memory), flash memory, or any combination of such memories. The system memory 420 may also include an operating system 430 that controls the operation of the computing device 400 and one or more program modules 440. The program modules 440 may be responsible for executing one or more operations of forming an enclosure. While being executed by the processing unit 410, the program modules 440 may perform the various processes described above.

The computing device 400 may also have additional features or functionality. For example, the computing device 400 may include additional data storage devices (e.g., removable and/or non-removable storage devices) such as, for example, magnetic disks, optical disks, or tape. These additional storage devices are labeled as a removable storage 460 and a non-removable storage 470.

Examples of the disclosure may also be practiced in an electrical circuit comprising discrete electronic elements, packaged or integrated electronic chips containing logic gates, a circuit utilizing a microprocessor, or on a single chip containing electronic elements or microprocessors. For example, examples of the disclosure may be practiced via a system-on-a-chip (SOC) where each or many of the components illustrated in FIG. 4 may be integrated onto a single integrated circuit. Such a SOC device may include one or more processing units, graphics units, communications units, system virtualization units and various application functionality all of which are integrated (or “burned”) onto the chip substrate as a single integrated circuit.

When operating via a SOC, the functionality, described herein, may be operated via application-specific logic integrated with other components of the computing device 400 on the single integrated circuit (chip). The disclosure may also be practiced using other technologies capable of performing logical operations such as, for example, AND, OR, and NOT, including but not limited to mechanical, optical, fluidic, and quantum technologies.

The computing device 400 may include one or more communication systems 480 that enable the computing device 400 to communicate with other computing devices 495 or systems. Examples of communication systems 480 include, but are not limited to, wireless communications, wired communications, cellular communications, radio frequency (RF) transmitter, receiver, and/or transceiver circuitry, a Controller Area Network (CAN) bus, a universal serial bus (USB), parallel, serial ports, etc.

The computing device 400 may also have one or more input devices and/or one or more output devices shown as input/output devices 485. These input/output devices 485 may include a keyboard, a sound or voice input device, haptic devices, a touch, force and/or swipe input device, a display, speakers, etc. The aforementioned devices are examples and others may be used.

The computing device 400 may also include one or more sensors 490. The sensors may be image sensors that are used to determine whether the enclosure has been formed, whether the markings have been formed or to otherwise inspect the semiconductor package.

Based on the above, examples of the present disclosure describe a method for encapsulating an electronic device, the method comprising: providing a substrate having a first side with a plurality of components secured thereto; and three-dimensional (3D) printing a mold compound on the first side of the substrate such that the mold compound covers the plurality of components. In an example, the mold compound comprises a thermosetting liquid resin. In an example, the method also includes curing the 3D printed mold compound as part of a curing process. In an example, the method also includes forming a mark on an outer surface of the 3D printed mold compound as part of the curing process. In an example, the curing process includes: activating one or more ultraviolet light sources on a thermosetting liquid resin to form an enclosure around the plurality of components. In an example, activating the one or more ultraviolet light sources comprises selectively activating the one or more ultraviolet light sources. In an example, the one or more ultraviolet light sources are selectively activated based, at least in part, on a layer of the enclosure being formed. In an example, the one or more ultraviolet light sources are selectively activated based, at least in part, on a shape of the enclosure being formed. In an example, the one or more ultraviolet light sources are selectively activated based, at least in part, on a marking to be included on the enclosure.

Other examples describe a semiconductor package, comprising: a substrate; a plurality of electronic components mounted on the substrate; and an enclosure at least partially surrounding the plurality of electronic components, the enclosure being formed by a three-dimensional (3D) printing process in which the plurality of electronic components are immersed in a thermosetting liquid resin. In an example, the 3D printing process includes a curing process in which one or more ultraviolet lights are selectively activated. In an example, the enclosure includes a marking. In an example, the marking was formed during the curing process. In an example, the enclosure has a shape that was formed by selectively activating the one or more ultraviolet lights.

Examples of the present disclosure also describe a semiconductor package, comprising: a substrate; at least one semiconductor die mounted on the substrate; a communication means electrically coupling the at least one semiconductor die to the substrate; and a three-dimensional (3D) printed enclosing means at least partially surrounding the at least one semiconductor die and the communication means. In an example, the semiconductor package also includes a marking formed on the 3D printed enclosing means. In an example, the 3D printed enclosing means and the marking formed on the 3D printed enclosing means were formed as part of a 3D printing process. In an example, the 3D printed enclosing means is cured and the marking is formed by selectively activating one or more ultraviolet light sources during a curing process. In an example, the 3D printed enclosing means comprises a thermosetting liquid resin. In an example, the at least one semiconductor die is a NAND memory die.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method for encapsulating an electronic device, the method comprising:
providing a substrate having a first side with a plurality of components secured thereto; and
three-dimensional (3D) printing a mold compound on the first side of the substrate such that the mold compound covers the plurality of components.

2. The method of claim 1, wherein the mold compound comprises a thermosetting liquid resin.

3. The method of claim 1, further comprising curing the 3D printed mold compound during a curing process.

4. The method of claim 3, further comprising forming a mark on an outer surface of the 3D printed mold compound as part of the curing process.

5. The method of claim 3, wherein the curing process includes:
activating one or more ultraviolet light sources on a thermosetting liquid resin to form an enclosure around the plurality of components.

6. The method of claim 5, wherein activating the one or more ultraviolet light sources comprises selectively activating the one or more ultraviolet light sources.

7. The method of claim 6, wherein the one or more ultraviolet light sources are selectively activated based, at least in part, on a layer of the enclosure being formed.

8. The method of claim 6, wherein the one or more ultraviolet light sources are selectively activated based, at least in part, on a shape of the enclosure being formed.

9. The method of claim 6, wherein the one or more ultraviolet light sources are selectively activated based, at least in part, on a marking to be included on the enclosure.

10. A semiconductor package, comprising:
a substrate;
a plurality of electronic components mounted on the substrate; and
an enclosure at least partially surrounding the plurality of electronic components, the enclosure being formed by a three-dimensional (3D) printing process in which the plurality of electronic components are immersed in a thermosetting liquid resin.

11. The semiconductor package of claim 10, wherein the 3D printing process includes a curing process in which one or more ultraviolet lights are selectively activated.

12. The semiconductor package of claim 10, wherein the enclosure includes a marking.

13. The semiconductor package of claim 12, wherein the marking was formed during a curing process.

14. The semiconductor package of claim 10, wherein the enclosure has a shape that was formed by selectively activating one or more ultraviolet lights as part of a curing process.

15. A semiconductor package, comprising:
a substrate;
at least one semiconductor die mounted on the substrate;
a communication means electrically coupling the at least one semiconductor die to the substrate; and
a three-dimensional (3D) printed enclosing means at least partially surrounding the at least one semiconductor die and the communication means.

16. The semiconductor package of claim 15, further comprising a marking formed on the 3D printed enclosing means.

17. The semiconductor package of claim 16, wherein the 3D printed enclosing means and the marking formed on the 3D printed enclosing means were formed as part of a 3D printing process.

18. The semiconductor package of claim 17, wherein the 3D printed enclosing means is cured and the marking is formed by selectively activating one or more ultraviolet light sources during a curing process.

19. The semiconductor package of claim 15, wherein the 3D printed enclosing means comprises a thermosetting liquid resin.

20. The semiconductor package of claim 15, wherein the at least one semiconductor die is a NAND memory die.
